(19) United States
(12) Patent Application Publication
(10) Pub. No.: US 2014/0090684 A1
(43) Pub. Date: Apr. 3, 2014

(54) HETEROJUNCTION ELECTRODE WITH TWO-DIMENSIONAL ELECTRON GAS AND SURFACE TREATMENT

(71) Applicant: Joshua R. Smith, Washington, DC (US)

(72) Inventor: Joshua R. Smith, Washington, DC (US)

(21) Appl. No.: 14/035,628

(22) Filed: Sep. 24, 2013

Related U.S. Application Data
(60) Provisional application No. 61/705,073, filed on Sep. 24, 2012.

(51) Int. Cl. H01L 35/30; H01L 35/34

(52) U.S. Cl. CPC H01L 35/30; H01L 35/34
USPC 136/204; 438/20

(57) ABSTRACT

Techniques are provided for enhancing electrical properties of semiconductor structures. At a semiconductor structure, a heterojunction interface is provided between two dissimilar materials such that a two-dimensional electron gas (2DEG) region is present in the vicinity of the heterojunction. Energy is added to the semiconductor structure such that electrons that are present in the 2DEG region are promoted from below the Fermi level to energy states sufficiently high that the electrons can escape the structure. Electrons are emitted from the semiconductor structure in response to adding the energy such that electrons escape the surface of the semiconductor structure.

### CROSS REFERENCE TO RELATED APPLICATIONS

This application claims priority from U.S. Provisional Application No. 61/705,073 filed on Sep. 24, 2012, the entirety of which is incorporated by reference herein.

### TECHNICAL FIELD

The techniques presented herein relate to applications of an enhanced electrode structure.

### BACKGROUND

An electrode is a structure that operates as an electrical conductor to emit electrons into or collect electrons from a region of space. For example, electrodes may be composed of conductive or semiconductive materials, and the properties of electron emission and electron collection to and from the electrodes may be affected or otherwise dependent on the materials' composition. Electrodes may typically reside in a vacuum or near-vacuum environment. In such an environment, one particular electrode may be designated or classified as a cathode, and another particular electrode may be designated or classified as an anode based on, for example, the electrical qualities of the respective electrodes. For example, the cathode electrode is configured to emit electrons into the vacuum and the anode electrode is configured to collect electrons from the vacuum. Thus, the cathode electrode may also be referred to as an “emitter” and the anode electrode may also be referred to as a “collector.” Electrodes may be composed of many different materials. For example, electrodes may be homogenous electrodes that are composed entirely of the same or substantially the same material, while heterogenous electrodes may be composed of two more materials that are entirely or substantially different from one another.

### BRIEF DESCRIPTION OF THE DRAWINGS

FIG. 1 shows an example diagram depicting an electrode that is used as a cathode.

FIG. 2 shows an example diagram depicting an electrode that is used as an anode.

FIG. 3 shows an example diagram depicting a heterojunction electrode.

FIG. 4 shows an example energy band diagram for the heterojunction electrode.

FIG. 5 shows an example energy band diagram for the heterojunction electrode exhibiting a negative electron affinity.

FIG. 6 shows an example schematic diagram of a thermionic energy conversion device.

FIG. 7 shows an example energy diagram of the thermionic energy conversion device.

FIGS. 8A-8E show example energy diagrams for a thermionic energy conversion device with one or more heterojunction electrodes.

FIG. 9 shows an example schematic diagram of a refrigerator device with one or more heterojunction electrodes.

FIGS. 10A and 10B show example energy diagrams for a refrigerator device with one or more heterojunction electrodes.

### DETAILED DESCRIPTION

### Overview

Techniques are provided for enhancing electrical properties of semiconductor structures. In a semiconductor structure, a heterojunction interface is provided between two dissimilar materials such that a two-dimensional electron gas (2DEG) region is present in the vicinity of the heterojunction. Energy is added to the semiconductor structure such that electrons that are present in the 2DEG region are promoted from below the Fermi level into energy states sufficiently high that the electrons can escape the semiconductor structure. Electrons are emitted from the semiconductor structure in response to adding the energy such that electrons escape the surface of the semiconductor structure.

### Example Embodiments

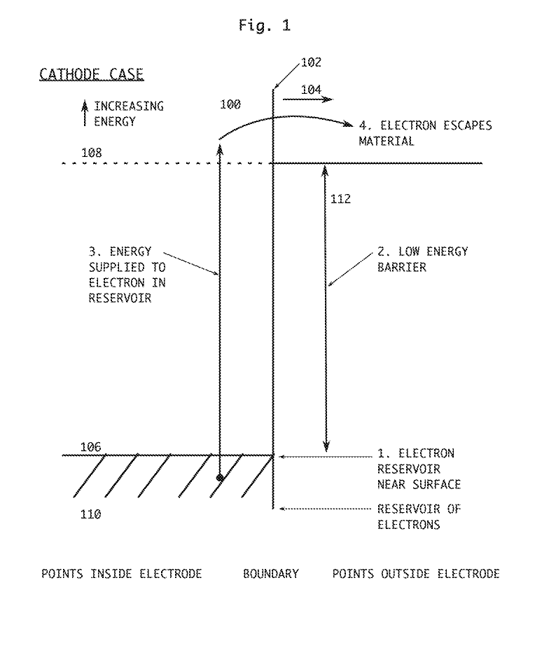

Reference is first made to FIG. 1. FIG. 1 shows an example diagrammatic representation of an electrode structure 100. The electrode structure 100 is also referred to hereinafter as an “electrode.” The electrode 100 in FIG. 1 is depicted as a cathode, though it should be appreciated that the depiction of the electrode as the cathode is merely an example. The electrode 100 has a boundary 102, which may be made of any physical composition. The portion outside of the electrode 100 (e.g., beyond the boundary 102 of the electrode 100) is referred to as “outside the electrode”. Outside the electrode 100 is depicted at reference numeral 104, and the outside portion 104 may also be referred to as vacuum 104 or atmosphere 104. It should be appreciated that the term “vacuum,” as used herein, may be used to describe a complete vacuum or a substantially complete vacuum. The term “atmosphere,” as used herein, may be used to describe relative atmospheric conditions (e.g., composition and pressure) when compared to conditions within the electrode 100. In general, the terms “electrode,” “cathode,” “vacuum” and “atmosphere,” among other terms, are commonly understood by those with ordinary skill in the technical area described herein.

FIG. 1 depicts a plurality of energy states within the electrode 100. In materials in the solid state, particularly metals and semiconductors, electrons tend to accumulate in lower energy states within the material and produce a reservoir or “sea” of electrons distributed throughout the material; reference numeral 110 depicts this accumulation of electrons in low energy states. Reference numeral 106 depicts the “top” of this electron reservoir; in a metal, practitioners skilled in the art would understand the “top” to refer to the Fermi level, whereas in a semiconductor, the “top” would be understood to refer to the valence band maximum. At the surface 102 of the electrode 100 exists an energy barrier which traps electrons within the material; the top of this energy barrier is depicted with reference numeral 108 and the energy barrier itself is depicted with reference numeral 112.

Energy may be added to an electron or electrons residing the reservoir 110. If a sufficient amount of energy is added to the electron in the reservoir 110, the energy increase of the electron may be greater than the energy barrier 112. If the electron is in the vicinity of, and moving towards the surface 102, the electron may cross the surface 102 and escape to outside the electrode 104. Thus, since electrons may be emitted from the electrode 100 in response to a sufficient energy stimulus, the electrode 100 in FIG. 1 (e.g., cathode) may also be referred to as an emitter.

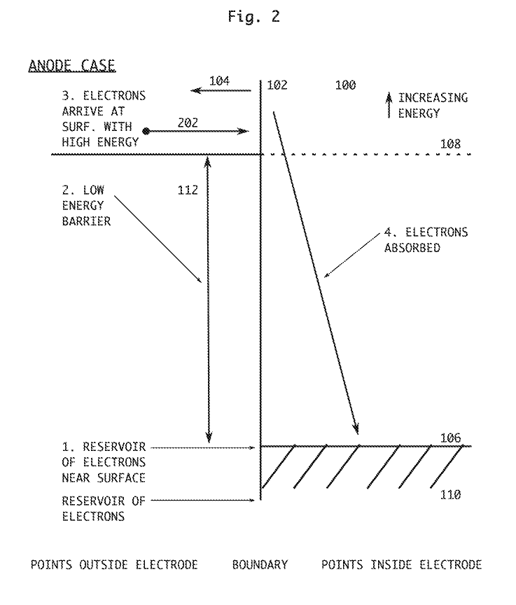

Reference is now made to FIG. 2. FIG. 2 shows an example diagrammatic representation of the electrode 100 operating as an anode. The term “anode” is commonly understood by those with ordinary skill of the technical area described herein. In FIG. 2, the electrode is shown at 100, and the electrode boundary is shown at 102. The outside portion or vacuum is shown at 104. As described in FIG. 1, the electrode 100 has energy barrier 112 who's top is located at reference numeral 108. As depicted in FIG. 2 at reference numeral 202, an electron arrives at the surface of the electrode 100 from a point outside of the electrode. The electron has a sufficiently high energy, and thus, the electron is absorbed into the electrode and joins other electrons in the electron reservoir.

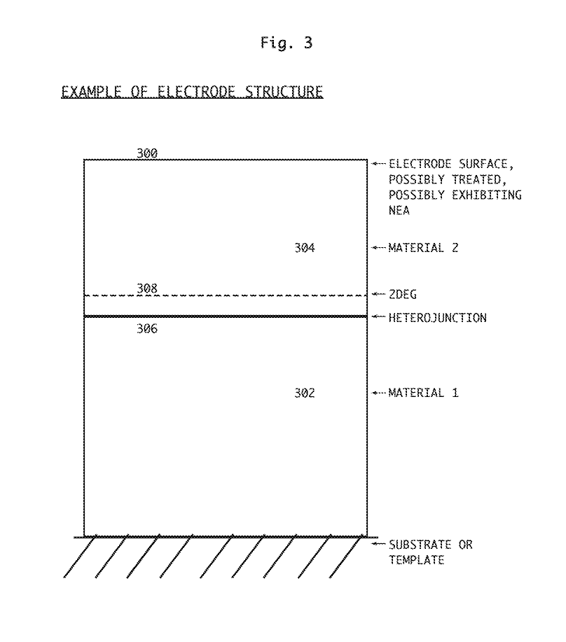

Reference is now made to FIG. 3, which shows an example heterojunction electrode at reference numeral 300. The heterojunction electrode 300 in FIG. 3 may be, for example, an electrode with an interface between two dissimilar materials. Example heterojunctions include materials that comprise GaN/AlGaN and GaAs/AlGaAs, though it should be appreciated that these are merely examples. For simplicity, FIG. 3 shows a first material at reference numeral 302 and a second material at reference numeral 304, and the heterojunction between the first material 302 and the second material 304 is shown at reference numeral 306. Certain heterojunctions create a so-called two-dimensional electron gas (“2DEG”) region, which is shown at reference numeral 308. The 2DEG is a region of electrons which are narrowly geometrically constrained in the vertical dimension of FIG. 3, but are unconstrained along the lateral dimensions, parallel to the heterojunction.

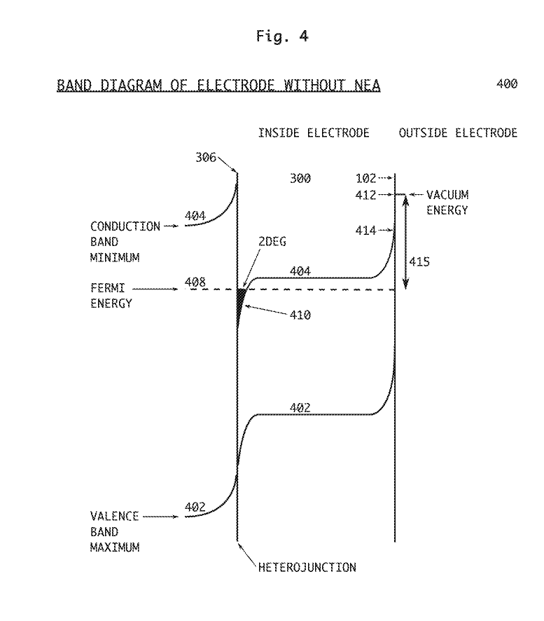

Reference is now made to FIG. 4. FIG. 4 shows an example band diagram 400 for the heterojunction electrode 300. The band diagram 400 depicts the valence band maximum 402 and conduction band minimum 404. Electrons may occupy energy states below the valence band minimum 402, or above the conduction band maximum 404, but cannot generally occupy states in the bandgap between 402 and 404. As shown, the valence band edge 402 and the conduction band edge 404 may change at the boundary of the heterojunction 306. FIG. 4 also depicts the Fermi level 408. The Fermi level 408 parameterizes the energy distribution of electrons within the material; practitioners skilled in the art generally understand that electrons with energy above the Fermi level are mobile within the material and can conduct electrical current whereas electrons with energy below the Fermi level are fixed. Additionally, at reference numeral 410, FIG. 4 shows the 2DEG region, which is formed near the heterojunction of the materials in the electrode. At the surface of the electrode (e.g., the boundary 102 of the electrode 300), the vacuum energy is shown at reference numeral 412. The vacuum energy 412 is above the conduction band minimum at the surface of the electrode. The conduction band minimum at the surface of the electrode is shown at reference numeral 414. Thus, as shown, since the conduction band minimum 414 at the surface of the electrode is less than the vacuum energy 412, electrons at the surface of the electrode not only require energy to be promoted into the conduction band, they must have additional energy to escape the electrode 300 over the vacuum energy 412.

As stated above, it may be desirable to increase the energy of electrons to a level that is above the vacuum energy 412 in order to emit electrodes from inside the electrode 300 to outside the electrode. Since the electrons in the 2DEG region 410 are already at a significantly higher energy level than the electrons in the valence energy band, as shown at reference numeral 402, it may be more desirable to increase the energy (i.e. “elevate” the energy) of the electrons in the 2DEG region to a level that is at or above the vacuum energy than to increase the energy of the electrons in the valence energy band 402. For example, since the electrons in the 2DEG region 410 reside at higher energy states than the electrons in the valence band 402 (and thus are closer in energy to the vacuum energy 412), a smaller amount of energy may be added to the electrons in the 2DEG region 410 to excite or enhance the energy states of these electrons to a level at or above the vacuum energy level 412, particularly when compared to the amount of energy that is needed to excite or enhance the energy of the electrons in the valence band 402 to a similar energy level. In one example, energy may be added to the electrons in the 2DEG region via light (e.g., photons), heat, nuclear radiation (e.g., alpha, beta, gamma radiation, etc.) or some other energy source.

As shown in FIG. 4, at reference numeral 415 (i.e. emission barrier), the vacuum energy level 412 can be adjusted via surface treatments to the electrode 300 or via an externally applied electric field. Thus, by lowering the vacuum energy level 412 the amount of energy required to excite the electrons in the 2DEG region 410 or the valence band below 402 to a level above the vacuum energy 412 is also reduced.

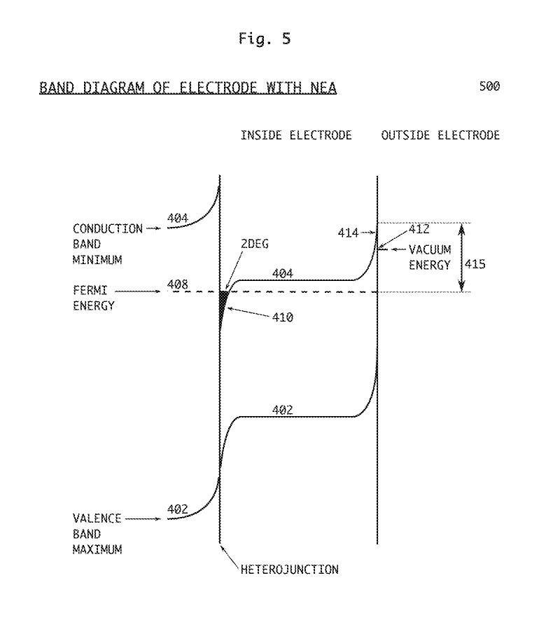

Reference is made to FIG. 5, which shows a band diagram 500. FIG. 5 shows many components that are similar or substantially similar to those depicted in FIG. 4. In particular, FIG. 5 shows the valence band maximum 402, the conduction band minimum 404, the Fermi level 408, the 2DEG region 410, the vacuum energy level 412. However, in FIG. 5, the vacuum energy level 412 has been adjusted to a level that is below the conduction band minimum 414 at the surface of the electrode. Thus, the electrode in FIG. 5 is said to have a Negative Electron Affinity (or NEA), which indicates a scenario in which, at the surface of the electrode, the vacuum energy is below the conduction band minimum. Thus, it should be appreciated that the surface of an electrode may acquire an NEA as a result of surface treatment applied to the electrode. In the case of NEA, the barrier to electron emission is the difference between the conduction band minimum at the surface 414 and the Fermi level 408 in contrast to the barrier of electrode 400 depicted in FIG. 4. These techniques for reducing the vacuum energy are merely examples.

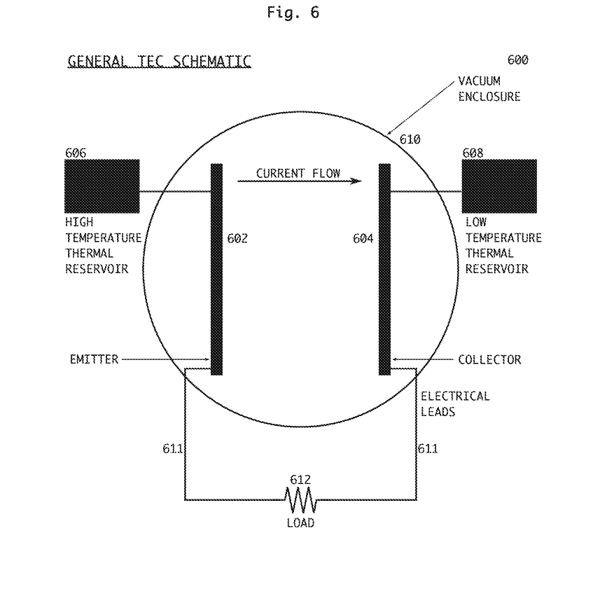

Reference is now made to FIG. 6. FIG. 6 shows a schematic diagram of a thermionic energy conversion (“TEC”) device 600. In general, a TEC is a device which converts heat direct into electrical work. As shown in FIG. 6, the TEC comprises an emitter electrode 602 and a collector electrode 604 enclosed by an enclosure 610. This enclosure 610 may be evacuated, partially evacuated, or contain some atmosphere of a gas or mixture of gases. The emitter electrode 602 is in thermal contact with a thermal reservoir, shown at reference numeral 606. The collector electrode 604 is in thermal contact with a thermal reservoir, shown at reference numeral 608. The temperature of the thermal reservoir 606 is higher than that of the thermal reservoir 608. Electrons are emitted from the emitter electrode 602, and travel across the interelectrode space (e.g. depicted by the gap between the emitter electrode 602 and collector electrode 604), and are absorbed at the collector electrode 604. The electrons travel through electrical lead 611 and through an external load, shown at reference numeral 612. Work is performed on the external load 612, and the electrons are carried back to the emitter electrode 602 to complete the circuit.

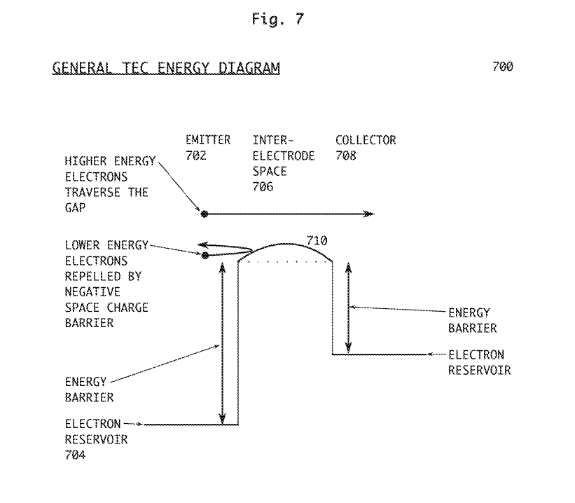

Reference is made to FIG. 7, which shows an example energy diagram 700 of a TEC depicting a negative space charge energy barrier. In the emitter electrode 702, energy is added to the electrons in the electron reservoir 704, and some electrons escape into the interelectrode space 706. As more electrons appear in the interelectrode space 706, a net negative charge develops and the net negative charge creates an additional energy barrier 710. Some electrons emitted from the emitter electrode 702 do not have sufficient energy to overcome this space charge barrier 710. If either the emitter electrode 702 or the collector electrode 708 (or both) exhibit a negative electron affinity, the negative space charge barrier can be reduced or eliminated (e.g., to offset the net negative charge), thus improving the performance of the TEC.

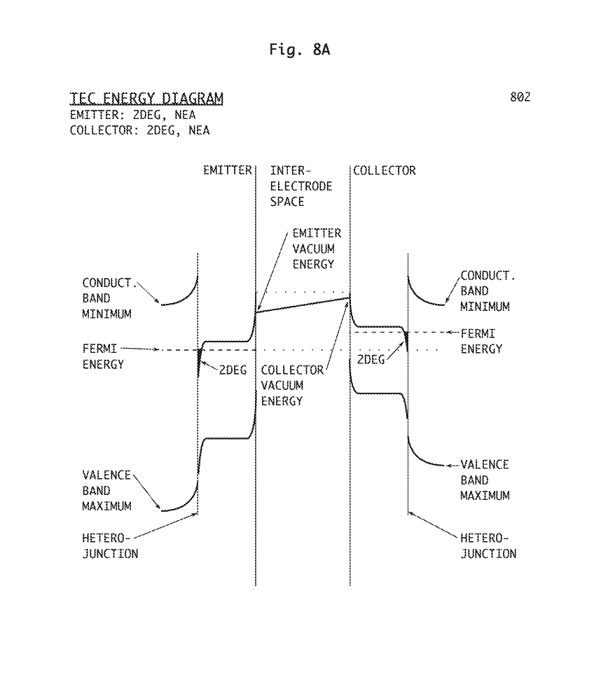

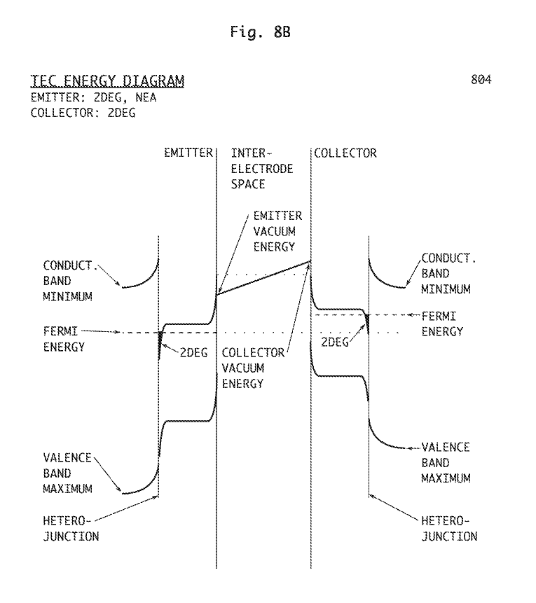

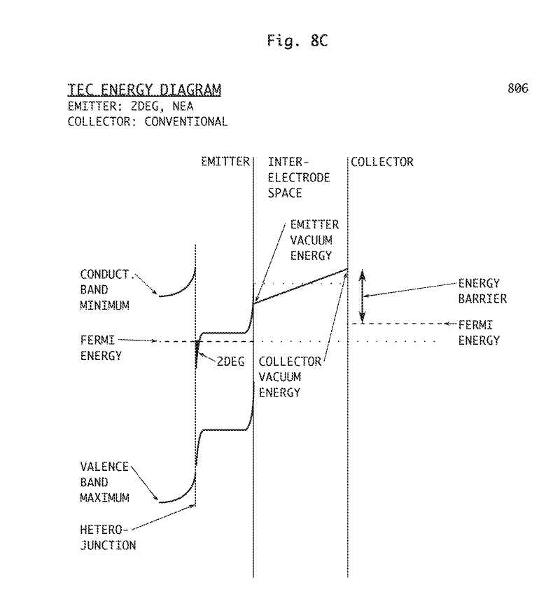

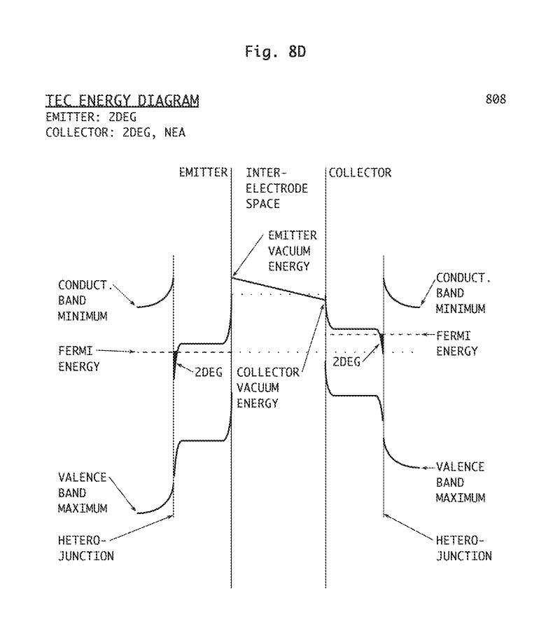

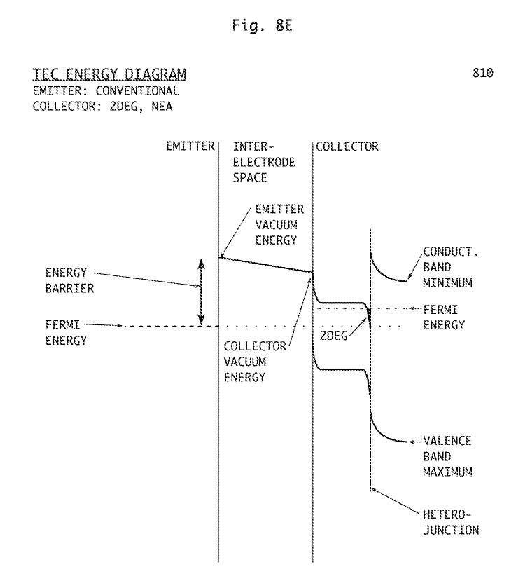

Reference is now made to FIGS. 8A-8E. FIGS. 8A-8E show energy diagrams for the TEC with variations of the type of emitter electrode and/or collector electrode. In FIG. 8A, the energy band diagram 802 for the TEC includes an emitter electrode featuring a 2DEG heterojunction and NEA as well as a collector electrode also featuring a 2DEG heterojunction and NEA. The negative space charge barrier is not shown for sake of simplicity. In FIG. 8B, the energy diagram 804 for the TEC is shown where the emitter electrode is a 2DEG electrode featuring NEA and the collector electrode is a 2DEG electrode. In FIG. 8C, the energy diagram 806 for the TEC shown where the emitter electrode is a 2DEG electrode featuring an NEA and the collector electrode is a conventional electrode. In FIG. 8D, the energy diagram 808 for the TEC is shown where the emitter electrode is a 2DEG electrode and the collector electrode is a 2DEG electrode featuring an NEA. In FIG. 8E, the energy diagram 810 for the TEC is shown where the emitter electrode is a conventional electrode and where the collector electrode is a 2DEG electrode featuring an NEA. Each of the configurations depicted in FIGS. 8A to 8E optimize performance by some combination of reducing/eliminating the negative space charge effect, increasing the emission current from the emitter, or improving the electrical properties of the overall system. The particular configuration is chosen according to the application to which the system is applied.

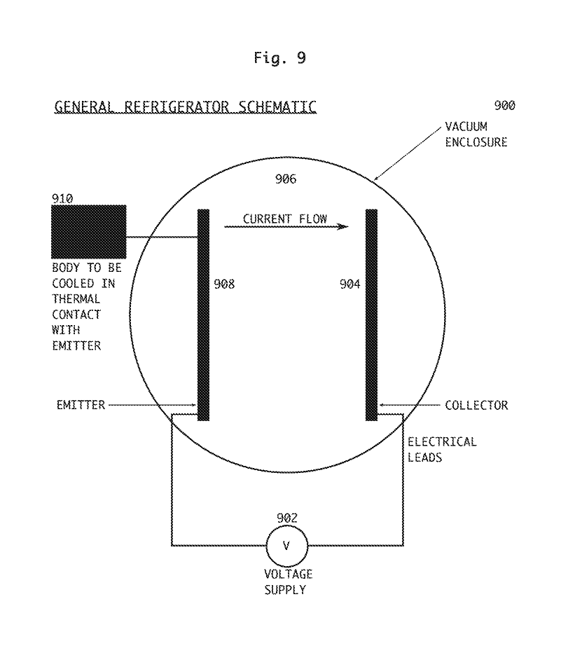

Reference is now made to FIG. 9. FIG. 9 shows a general schematic 900 of an example implementation of a refrigerator configuration. In the refrigerator configuration, work is done by the refrigerator to move heat from a thermal reservoir at a higher temperature to a thermal reservoir at a lower temperature. In FIG. 9, an external voltage supply 902 biases a collector electrode 904 such that electrons are accelerated across the interelectrode space 906 between the emitter electrode 908 and the collector electrode 904. Heat is carried by electrons escaping the emitter and thereby cools the emitter electrode and any body in thermal contact with the emitter electrode, depicted with numeral 910.

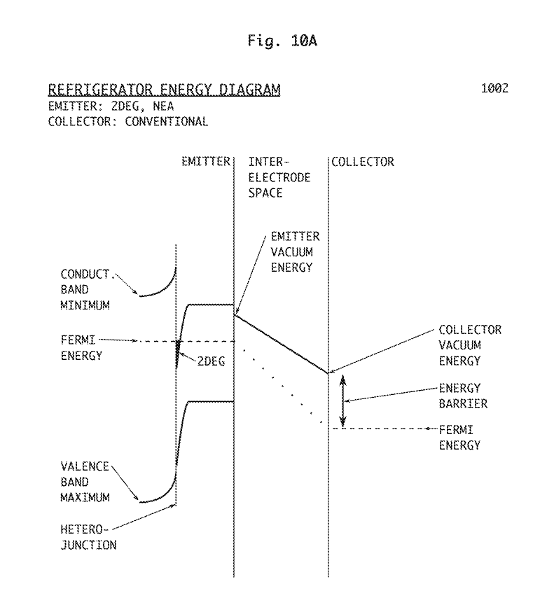

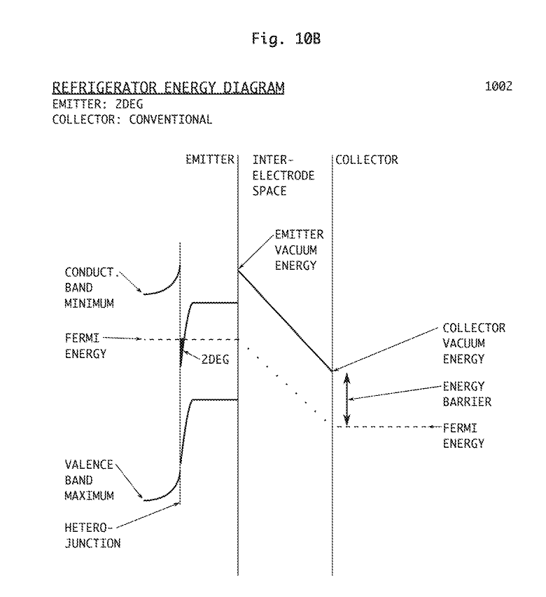

Referring now to FIGS. 10A and 10B, energy diagrams for the a refrigeration device are shown. In FIG. 10A the energy diagram 1002 of the refrigeration device is shown, where the emitter electrode is a 2DEG electrode featuring NEA, and the collector electrode is a conventional electrode. In FIG. 10B, the energy diagram 1004 of the refrigeration device is shown, where the emitter electrode is a 2DEG electrode and the collector electrode is a conventional electrode.

In sum, a method for enhancing electrical properties of a material, comprising: at a semiconductor structure, providing a heterojunction interface between two dissimilar materials such that a two-dimensional electron gas (2DEG) region is present in a vicinity of the heterojunction; adding energy to the semiconductor structure such that electrons that are present in the 2DEG region are promoted from energy states below the Fermi level to energy states sufficiently high that the electrons can escape the structure; and emitting electrons from the semiconductor structure in response to adding the energy such that electrons escape the surface of the semiconductor structure.

In addition, a system is provided comprising: an enclosed multi-electrode system where the enclosure is evacuated, partially evacuated, or consists of an atmosphere of a gas or mixture of gases and one or more of the electrodes have a heterojunction interface between two dissimilar materials such that a two-dimensional electron gas (2DEG) region is present in the vicinity of the heterojunction. At least one of the electrodes is an emitter electrode and one is a collector electrode. Energy is added to the electrons in the emitter electrode such that electrons in states below the Fermi level are promoted to energy states sufficiently high that the electrons can escape the electrode, and emitting electrons from the surface of the electrode in response to adding the energy such that electrons escape the surface of the emitter electrode. Any of the electrodes in the system may have a surface treatment that lowers the emission barrier by lowering the electrode's vacuum energy below its non-treated state; or the same result may be achieved by the application of an external electric field. The surface treatment may also result in a condition where the vacuum energy of the surface falls below the conduction band minimum; a condition known to practitioners in the art as negative electron affinity.

The above description is intended by way of example only. Various modifications and structural changes may be made therein without departing from the scope of the concepts described herein and within the scope and range of equivalents of the claims.

What is claimed is:

1. A method for enhancing electrical properties of a material, comprising:
at a semiconductor structure, providing a heterojunction interface between two dissimilar materials such that a two-dimensional electron gas (2DEG) region is present in a vicinity of the heterojunction;
adding energy to the semiconductor structure such that electrons that are present in the 2DEG region are promoted from below a Fermi level to energy states sufficiently high that the electrons can escape the structure; and
emitting electrons from the semiconductor structure in response to adding the energy such that electrons escape the surface of the semiconductor structure.

2. The method of claim 1, wherein adding comprises adding energy to the semiconductor structure via one or more light source, heat source, or nuclear radiation source.

3. The method of claim 1, further comprising lowering an energy barrier at a surface of the semiconductor structure by applying a surface treatment to the semiconductor structure or via an externally applied electric field.

4. The method of claim 3, wherein lowering comprises lowering the energy barrier at the surface of the semiconductor structure such that the energy barrier at the surface of the semiconductor structure is lower than the energy of the conduction band minimum at the surface of the semiconductor structure.

5. The method of claim 4, further comprising producing a negative electron affinity for the semiconductor device when the energy barrier at the surface of the semiconductor device is lower than the energy of the conduction band of the semiconductor device.

6. An enclosed multi-electrode system, comprising:
a first electrode structure and a second electrode structure, either or both of which has a heterojunction interface between two dissimilar materials such that a two-dimensional electron gas (2DEG) region is present in a vicinity of the heterojunction; and
an energy source that is configured to add energy to electrons in the first electrode structure such that the electrons in the first electrode structure that are below a Fermi level are promoted to energy states sufficiently high to enable the electrons to escape the first electrode structure.

7. The system of claim 6, wherein the first electrode structure is an emitter electrode structure and wherein the second electrode structure is a collector electrode structure.

8. The system of claim 7, wherein the emitter electrode is in thermal contact with a high temperature thermal reservoir and wherein the collector electrode is in thermal contact with a low temperature thermal reservoir.

9. The system of claim 7, wherein electrons are emitted from the emitter electrode and travel across an interelectrode space before being absorbed in the collector electrode.

10. The system of claim 9, wherein the electrons travel through an external load coupled to the emitter electrode and the collector electrode.

11. The system of claim 7, wherein the emitter electrode has a negative electron affinity resulting from a reduction in the vacuum energy at a surface of the emitter electrode.

12. The system of claim 7, wherein the collector electrode has a negative electron affinity resulting from a reduction in the vacuum energy at a surface of the collector electrode.

13. The system of claim 7, wherein the vacuum energy of the emitter electrode is lowered via a surface treatment.

14. The system of claim 7, wherein the vacuum energy of the emitter electrode is lowered via an externally applied electric field.

15. The system of claim 7, wherein the vacuum energy of the collector electrode is lowered via a surface treatment.

16. The system of claim 7, wherein the vacuum energy of the collector electrode is lowered via an externally applied electric field.

17. The system of claim 7, further comprising an external voltage source that is applied to the system such that electrons are accelerated across interelectrode space between the emitter electrode and collector electrode.

18. The system of claim 17, wherein the external voltage source is applied such that heat is carried by electrons escaping the emitter electrode and thereby cools the emitter electrode and any body in thermal contact with the emitter electrode.

19. The system of claim 6, wherein energy is added to electrons in the emitter electrode via one or more heat source, light source, or nuclear radiation source.
